(19) United States
(12) Patent Application Publication
(10) Pub. No.: US 2025/0198706 A1
(43) Pub. Date: Jun. 19, 2025

(54) GRAVITY HEAT DISSIPATION DEVICE

(71) Applicant: Auras Technology Co., Ltd., New Taipei City (TW)

(72) Inventors: Po-Chun CHIU, New Taipei City (TW); Che-Chia CHANG, New Taipei City (TW); Chien-Chih SU, New Taipei City (TW); Mu-Shu FAN, New Taipei City (TW)

(21) Appl. No.: 18/888,846

(22) Filed: Sep. 18, 2024

Related U.S. Application Data
(60) Provisional application No. 63/610,644, filed on Dec. 15, 2023.

(51) Int. Cl. F28D 15/04; F28D 15/02

(52) U.S. Cl. CPC F28D 15/04; F28D 15/0275; F28D 2015/0216; F28F 2250/08; F28F 2255/18

(57) ABSTRACT

A gravity heat dissipation device includes a fixed frame, a heat conduction block, a first heat pipe and a second heat pipe. The heat conduction block is installed in the fixed frame and used to contact a heat source. The first heat pipe is connected to the heat conduction block, and a connection portion of the first heat pipe is located below a heat absorption portion of the first heat pipe and a heat dissipation portion of the first heat pipe. The second heat pipe is connected to the heat conduction block and the first heat pipe, and a first connection portion is located above a heat absorption portion of the second heat pipe and a first heat dissipation portion of the second heat pipe.

### RELATED APPLICATIONS

This application claims priorities to U.S. Provisional Application Ser. No. 63/610,644, filed Dec. 15, 2023, the disclosures of which are incorporated herein by reference in their entireties.

### TECHNICAL FIELD

The present disclosure relates to a heat dissipation device. More particularly, the present disclosure relates to a gravity heat dissipation device.

### BACKGROUND

With the advancement of technology, electronic products have become more popular, and gradually changed the life or work of many people. As the calculating power of the computers increases, the temperature control of the electronic components such as the central processing units and graphics chips is more important.

Electronic components such as the central processing units and graphics chips generate heat during operation and require proper cooling to achieve the best performance. In order to keep the central processing unit and graphics chips operating at a proper temperature, an appropriate gravity heat dissipation device configuration may influence the performance of the electronic device.

In addition, when the appearance size of current electronic devices is getting smaller and the number of cores of the computing chip is increased, the heat generated by the computing chip is also increased. In a small space, not only the computing chip and the gravity heat dissipation device are installed, but other mechanisms and electronic components are also installed.

In order to fit the design of the chassis of the small computer equipment, some computer equipment may adopt the design of vertically mounted graphics cards to provide better space utilization. However, the vertically mounted graphics cards and the traditional graphics cards may produce different results in the performance test.

Therefore, there is a need to balance the performance of the vertically mounted graphics cards and the horizontally mounted graphics cards to improve heat dissipation efficiency and reduce the operating temperature of the computing chip so as to improve the overall working efficiency of the electronic device.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a gravity heat dissipation device to improve the heat dissipation efficiency and further improve the overall working efficiency of the electronic device.

To achieve these and other advantages and in accordance with the objective of the embodiments of the present invention, as the embodiment broadly describes herein, the embodiments of the present invention provides a gravity heat dissipation device including a fixing frame, a heat conduction block, a first heat pipe and a second heat pipe. The heat conduction block is installed in the fixing frame to contact a heat source, and the first heat pipe is connected to the heat conduction block. The first heat pipe includes a heat absorption portion, a connection portion and a heat dissipation portion. In addition, the connection portion of the first heat pipe is connected between the heat absorption portion of the first heat pipe and the heat dissipation portion of the first heat pipe, and the connection portion of the first heat pipe is located below the heat absorption portion of the first heat pipe and the heat dissipation portion of the first heat pipe. The second heat pipe is connected to the heat conduction block and the first heat pipe. In addition, the second heat pipe includes a heat absorption portion, a first connection portion and a first heat dissipation portion, the first connection portion of the second heat pipe is connected between the heat absorption portion of the second heat pipe and the first heat dissipation portion of the second heat pipe, and the first connection portion of the second heat pipe is located above the heat absorption portion of the second heat pipe and the first heat dissipation portion of the second heat pipe.

In some embodiments, the second heat pipe further includes a second connection portion and a second heat dissipation portion. The second connection portion is connected to and located below the heat absorption portion of the second heat pipe. The second heat dissipation portion is connected to the second connection portion of the second heat pipe.

In some embodiments, the gravity heat dissipation device further includes a third heat pipe connected to the heat conduction block and the second heat pipe. In addition, the third heat pipe includes a heat absorption portion, a first connection portion, a first heat dissipation portion, a second connection portion and a second heat dissipation portion. The first connection portion of the third heat pipe is connected between the heat absorption portion of the third heat pipe and the first heat dissipation portion of the third heat pipe, and the first connection portion of the third heat pipe is located above the heat absorption portion of the third heat pipe and the first heat dissipation portion of the third heat pipe, the second connection portion of the third heat pipe is connected to and located below the heat absorption portion of the third heat pipe, and the second heat dissipation portion of the third heat pipe is connected to the second connection portion of the third heat pipe.

In some embodiments, the second heat pipe and the third heat pipe in sequence are respectively disposed symmetrically on both sides of the first heat pipe.

In some embodiments, the gravity heat dissipation device further includes a fourth heat pipe connected to the heat conduction block and the third heat pipe, and the fourth heat pipe includes a heat absorption portion, a connection portion and a heat dissipation portion. In addition, the connection portion of the fourth heat pipe is connected between the heat absorption portion of the fourth heat pipe and the heat dissipation portion of the fourth heat pipe, and the connection portion of the fourth heat pipe is located below the heat absorption portion of the fourth heat pipe and located above the heat dissipation portion of the fourth heat pipe.

In some embodiments, the gravity heat dissipation device further includes a fifth heat pipe connected to the heat conduction block and the fourth heat pipe. In addition, the fifth heat pipe includes a heat absorption portion, a connection portion and a heat dissipation portion. The connection portion of the fifth heat pipe is connected to the heat absorption portion of the fifth heat pipe and the heat dissipation portion of the fifth heat pipe, and the connection portion of the fifth heat pipe is located below the heat absorption portion of the fifth heat pipe and above the heat dissipation portion of the fifth heat pipe.

In some embodiments, the second heat pipe, the third heat pipe, the fourth heat pipe and the fifth heat pipe in sequence are respectively disposed symmetrically on both sides of the first heat pipe.

In some embodiments, the gravity heat dissipation device further includes a first heat dissipation fin module. The heat absorption portion of the first heat pipe and the heat dissipation portion of the first heat pipe, the heat absorption portion of the second heat pipe and the first heat dissipation portion of the second heat pipe, the heat absorption portion of the third heat pipe and the first heat dissipation portion of the third heat pipe, the heat absorption portion of the fourth heat pipe, and the heat absorption portion of the fifth heat pipe are disposed inside the first heat dissipation fin module.

In some embodiments, the gravity heat dissipation device further includes a second heat dissipation fin module is separately disposed with the first heat dissipation fin module up and down. In addition, the second heat dissipation portion of the second heat pipe, the second heat dissipation portion of the third heat pipe, the heat dissipation portion of the fourth heat pipe and the heat dissipation portion of the fifth heat pipe are disposed inside the second heat dissipation fin module.

In some embodiments, the gravity heat dissipation device further includes a module fixing bracket and a fan module. The module fixing bracket is fixed on the first heat dissipation fin module and the second heat dissipation fin module. The fan module is fixed on the module fixing bracket.

In some embodiments, the fan module includes a fan fixing frame and a plurality of fans. The fan fixing frame is fixed on the module fixing bracket and the fans are installed on the fan fixing frame.

In some embodiments, the first heat pipe includes a metal tube, an internal ring gear layer and a powder sintered layer. The internal ring gear layer is formed on an inner wall of the metal tube, and the powder sintered layer is formed inside the internal ring gear layer. In addition, the internal ring gear layer of the first heat pipe includes a groove depth and a groove width, and the groove depth of the internal ring gear layer of the first heat pipe is about 40-60% of a groove depth of the second heat pipe, the groove width of the internal ring gear layer of the first heat pipe is about 30-50% of a groove width of the second heat pipe. In addition, a diameter of metal powders of the powder sintered layer of the first heat pipe is about 35-45% of a diameter of metal powders of a powder sintered layer of the second heat pipe.

Hence, the gravity heat dissipation device disclosed in the present invention may utilize the gravity heat pipe to effectively improve the performance of the vertically installed display card, reduce the operating temperature of the computing chip, and further improve the overall working efficiency of the electronics device. In addition, the gravity heat pipe is equipped with finer metal powder to form a sintered layer to effectively improve the capillary force so as to increase the heat dissipation performance. Furthermore, shallow grooves are used instead of deep grooves to further ensure the heat dissipation liquid smoothly moving therein to further improve the heat dissipation performance, thereby increasing the heat dissipation capacity of the gravity heat dissipation device. Therefore, the gravity heat dissipation device disclosed in the present invention is suitable for a vertically mounted graphics card device.

### BRIEF DESCRIPTION OF THE DRAWINGS

The disclosure can be more fully understood by reading the following detailed description of the embodiment, with reference made to the accompanying drawings as follows:

FIG. 1 illustrates a schematic front view of a gravity heat dissipation device according to one embodiment of the present invention;

FIG. 2 illustrates an exploded schematic diagram of a gravity heat dissipation device according to one embodiment of the present invention;

FIG. 3 illustrates an exploded schematic diagram of a portion of heat pipes of a gravity heat dissipation device according to one embodiment of the present invention;

FIG. 4 illustrates a schematic cross-sectional view of the heat absorption portion of the heat pipe of a gravity heat dissipation device according to one embodiment of the present invention; and

FIG. 5 illustrates a schematic cross-sectional view of a heat pipe of a gravity heat dissipation device according to one embodiment of the present invention.

### DETAILED DESCRIPTION OF THE PREFERRED EMBODIMENT

The following is a detailed description of the embodiments in conjunction with the accompanying drawings, but the provided embodiments are not intended to limit the scope of the disclosure, and the description of the structure and operation is not used to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are used in the drawings and the description to refer to the same or like parts.

In addition, the terms used in the entire description and the scope of the patent application, unless otherwise specified, usually have the usual meaning of each term used in this field, in the content disclosed here and in the special content. Some terms used to describe the disclosure are discussed below or elsewhere in this specification to provide additional guidance to those skilled in the art in the disclosure.

In the implementation mode and the scope of the present application, unless the article is specifically limited in the context, “a” and “the” can generally refer to a single or pluralities. In the steps, the numbering is only used to conveniently describe the steps, rather than to limit the sequence and implementation.

Secondly, the words “comprising”, “including”, “having”, “containing” and the like used in the present application are all open language, meaning including but not limited to.

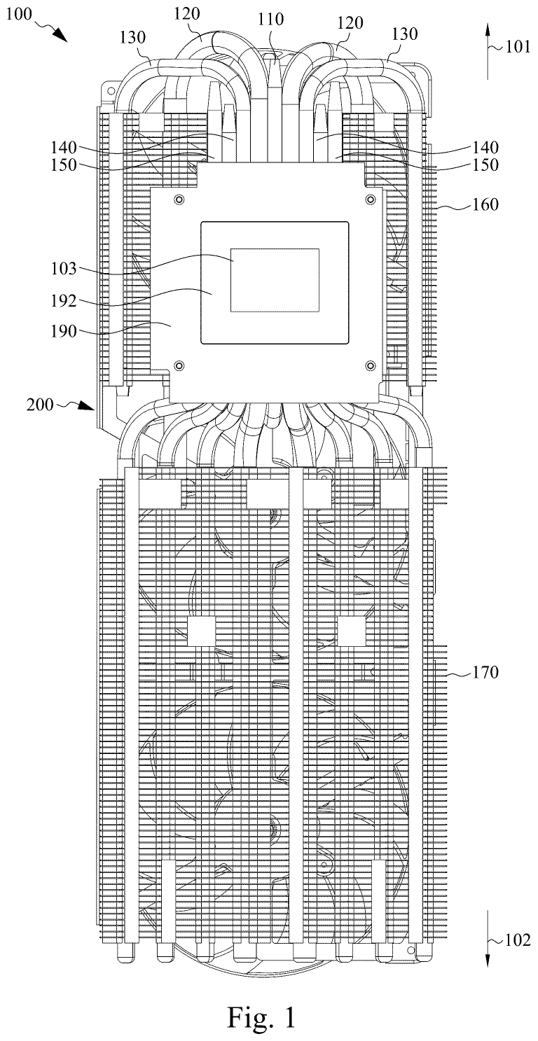

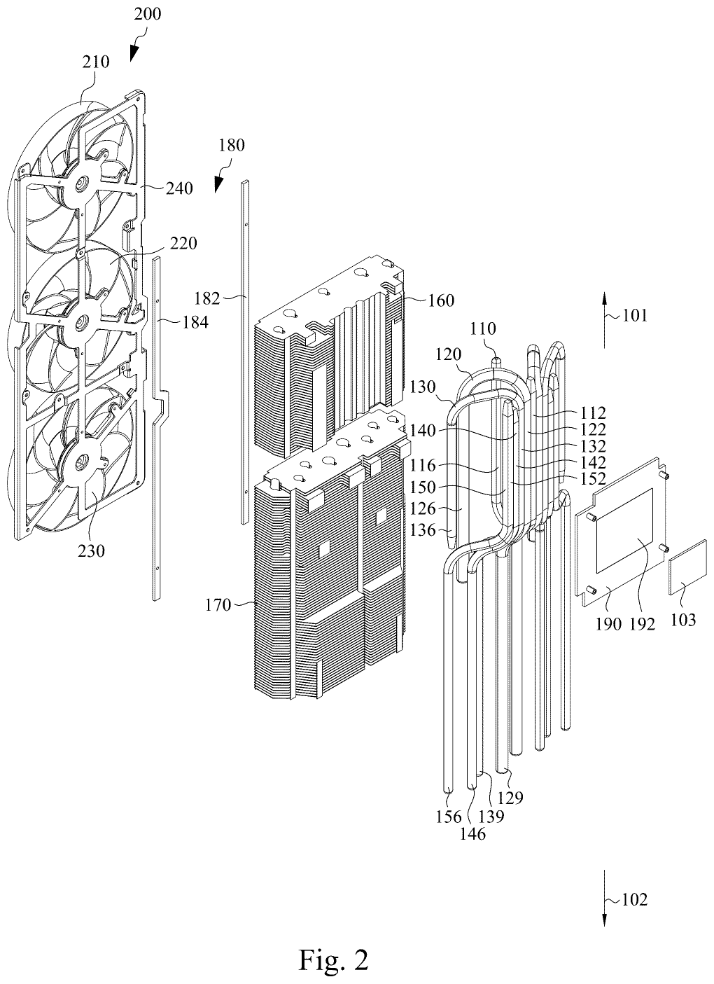

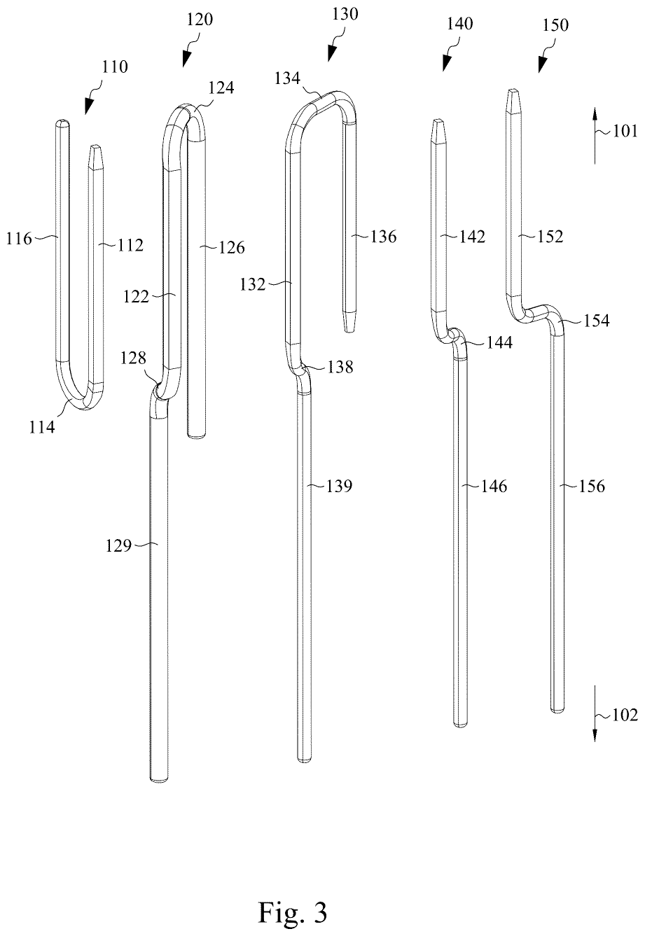

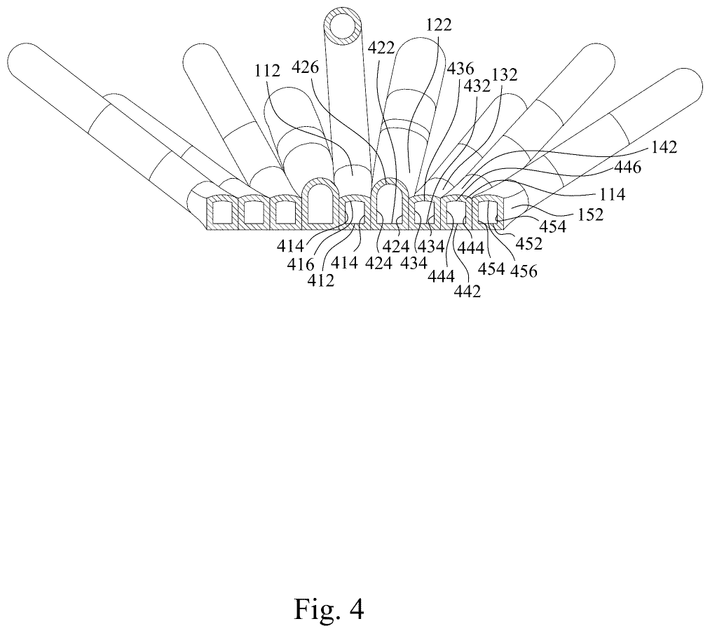

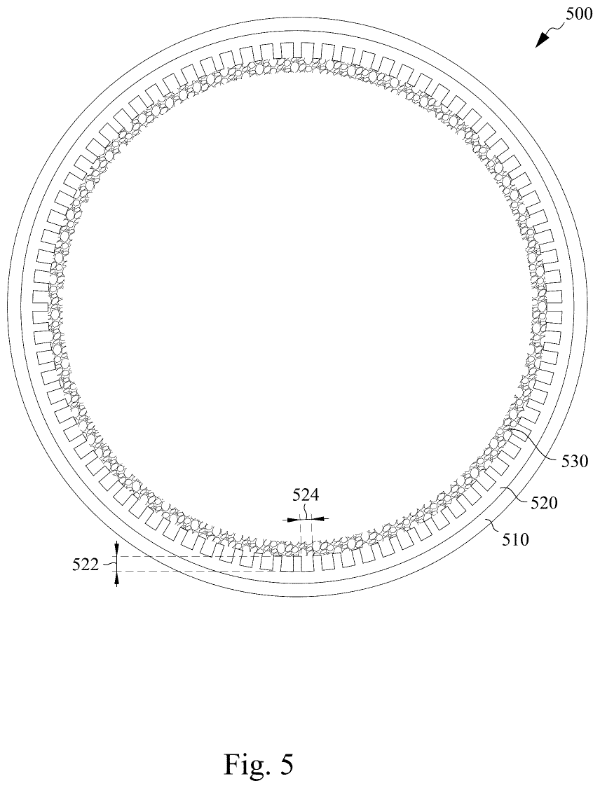

FIG. 1 is a schematic front view of a gravity heat dissipation device according to one embodiment of the present invention, FIG. 2 is an exploded schematic diagram thereof, FIG. 3 is an exploded schematic diagram of a portion of heat pipes thereof, and FIG. 4 is a schematic cross-sectional view of the heat absorption portion of the heat pipe thereof. In addition, FIG. 5 is a schematic cross-sectional view of the heat pipe.

First referring to FIGS. 1-3, the gravity heat dissipation device 100 includes a fixing frame 190, a heat conduction block 192, a first heat pipe 110 and a second heat pipe 120. The heat conduction block 192 is installed in the fixing frame 190 to contact a heat source 103, e.g. a chip or any other heating components, without departing from the spirit and protection scope of the present invention. In addition, FIG. 3 illustrates a portion of heat pipes, e.g. the first heat pipe 110 and heat pipes, for example, the second heat pipe 120, the third heat pipe 130, the fourth heat pipe 140 and the fifth heat pipe 150, respectively located beside the left side or the right side of the first heat pipe 110.

In some embodiments, the fixing frame 190 is made of aluminum metal, copper metal, stainless steel and other metals, and the heat conduction block 192 is made of copper metal and other metals, but the present invention is not limited thereto.

The first heat pipe 110 is connected to the heat conduction block 192 to absorb the heat generated from the heat source 103. The first heat pipe 110 includes a heat absorption portion 112, a connection portion 114 and a heat dissipation portion 116, and the connection portion 114 is connected between the heat absorption portion 112 and the heat dissipation portion 116. In addition, the connection portion 114 is located below the heat absorption portion 112 and the heat dissipation portion 116 to form a U-shaped heat pipe, and the opening of the U-shaped heat pipe is toward up, that is, the opening of the U-shaped heat pipe is toward the direction of the arrow 101.

The second heat pipe 120 is connected to the heat conduction block 192 to absorb the heat generated from the heat source 103. The second heat pipe 120 is connected to the first heat pipe 110. The second heat pipe 120 includes a heat absorption portion 122, a first connection portion 124 and a first heat dissipation portion 126. In addition, the first connection portion 124 is connected between the heat absorption portion 122 and the first heat dissipation portion 126, and the first connection portion 124 is located above the heat absorption portion 122 and the first heat dissipation portion 126 to form a U-shaped heat pipe by the heat absorption portion 112, the first connection portion 124 and the first heat dissipation portion 126, and the opening of the U-shaped heat pipe is toward downward, that is, the opening of the U-shaped heat pipe is toward the direction of the arrow 102.

In addition, the heat absorption portion 112 of the first heat pipe 110 and the heat absorption portion 122 of the second heat pipe 120 are preferably arranged in parallel, for example, arranged side by side on the surface of the heat conduction block 192.

In some embodiments, the second heat pipe 120 further includes a second connection portion 128 and a second heat dissipation portion 129. The second connection portion 128 is connected to the heat absorption portion 122 and located below the heat absorption portion 122, and the second connection portion 128 is connected to the second heat dissipation portion 129 and located above the second heat dissipation portion 129.

In some embodiments, the gravity heat dissipation device 100 includes a plurality of second heat pipes 120, for example, two second heat pipes 120, respectively disposed on two sides of the first heat pipe 110.

In some embodiments, the gravity heat dissipation device 100 further includes a third heat pipe 130 connected to the heat conduction block 192 to absorb the heat generated by the heat source 103. In addition, the third heat pipe 130 is connected to one side of the second heat pipe 120. The third heat pipe 130 includes a heat absorption portion 132, a first connection portion 134 and a first heat dissipation portion 136. The first connection portion 134 of the third heat pipe 130 is connected between the heat absorption portion 132 and the first heat dissipation portion 136, and the first connection portion 134 is located above the heat absorption portion 132 and the first heat dissipation portion 136 to form a U-shaped heat pipe, and the opening of the U-shaped heat pipe is toward downward, that is, the opening of the U-shaped heat pipe is toward the direction of the arrow 102.

In addition, the third heat pipe 130 further includes a second connection portion 138 and a second heat dissipation portion 139. The second connection portion 138 is connected to the heat absorption portion 132 and located below the heat absorption portion 132, and the second connection portion 138 is connected to the second heat dissipation portion 139 and located above the second heat dissipation portion 139.

In some embodiments, the gravity heat dissipation device 100 includes a plurality of third heat pipes 130, for example, two third heat pipes 130, respectively disposed beside the second heat pipes 120.

In some embodiments, the gravity heat dissipation device 100 further includes a fourth heat pipe 140 connected to the heat conduction block 192 to absorb the heat generated by the heat source 103. The fourth heat pipe 140 is connected to one side of the third heat pipe 130, and the fourth heat pipe 140 includes a heat absorption portion 142, a connection portion 144 and a heat dissipation portion 146. In addition, the connection portion 144 of the fourth heat pipe 140 is connected to the heat absorption portion 142 and the heat dissipation portion 146, and is located below the heat absorption portion 142 and above the heat dissipation portion 146.

In some embodiments, the gravity heat dissipation device 100 includes a plurality of fourth heat pipes 140, for example, two fourth heat pipes 140 respectively disposed on two sides of the third heat pipes 130.

In some embodiments, the gravity heat dissipation device 100 further includes a fifth heat pipe 150 connected to the heat conduction block 192 to absorb the heat generated by the heat source 103. The fifth heat pipe 150 is connected to one side of the fourth heat pipe 140, and the fifth heat pipe 150 includes a heat absorption portion 152, a connection portion 154 and a heat dissipation portion 156. In addition, the connection portion 154 of the fifth heat pipe 150 is connected to the heat absorption portion 152 and the heat dissipation portion 156, and located below the heat absorption portion 152 and above the heat dissipation portion 156.

In some embodiments, the gravity heat dissipation device 100 includes a plurality of fifth heat pipes 150, for example, two fifth heat pipes 150 respectively disposed beside the fourth heat pipes 140.

It is worth noting that the gravity heat dissipation device 100 further includes a first heat dissipation fin module 160 and a second heat dissipation fin module 170. The heat absorption portion 112 of the first heat pipe 110 and the heat dissipation portion 116 of the first heat pipe 110, the heat absorption portion 122 of the second heat pipe 120 and the first heat dissipation portion 126 of the second heat pipe 120, the heat absorption portion 132 of the third heat pipe 130 and the first heat dissipation portion 136 of the third heat pipe 130, the heat absorption portion 142 of the fourth heat pipe 140, and the heat absorption portion 152 of the fifth heat pipe 150 are all disposed inside the first heat dissipation fin module 160.

The second heat dissipation fin module 170 and the first heat dissipation fin module 160 are separately disposed up and down, but the present invention is not limited thereto. The second heat dissipation portion 129 of the second heat pipe 120, the second heat dissipation portion 139 of the third heat pipe 130, the heat dissipation portion 146 of the fourth heat pipe 140, and the heat dissipation portion 156 of the fifth heat pipe 150 are disposed inside the second heat dissipation fin module 170.

It is worth noting that the heat absorption portion 112 of the first heat pipe 110 and the heat dissipation portion 116 of the first heat pipe 110 are not disposed inside the second heat dissipation fin module 170.

When the top of the gravity heat dissipation device 100 is toward the direction of the arrow 101, the first heat pipe 110 may form a gravity heat pipe to effectively guide the conducted heat dissipation liquid to the connection portion 114 and further to the heat absorption portion 112 by the gravity and capillary phenomenon so as to improve the overall cooling efficiency of the gravity heat dissipation device 100 and uniformly distribute the heat to the cooling fins of the gravity heat dissipation device 100, thereby further improving the heat dissipation efficiency of the gravity heat dissipation device 100.

In some embodiments, the gravity heat dissipation device 100 further includes a module fixing bracket 180 and a fan module 200. The module fixing bracket 180 is fixed on the first heat dissipation fin module 160 and the second heat dissipation fin module 170, and the fan module 200 is fixed on the module fixing bracket 180 to conveniently install the fan module 200. In some embodiments, the module fixing bracket 180 includes a first fixing bracket 182 and the second fixing bracket 184 respectively fixed on the two sides of the first heat dissipation fin module 160 and the second heat dissipation fin module 170.

In some embodiments, the fan module 200 includes a fan fixing frame 240 and a plurality of fans, i.e. a first fan 210, a second fan 220 and a third fan 230. The fan fixing frame 240 is utilized to fix on the module fixing bracket 180, and the first fan 210, the second fan 220 and the third fan 230 are respectively fixed on the fan fixing frame 240 to conveniently fix on the module fixing bracket 180, and further fix on the first heat dissipation fin module 160 and the second heat dissipation fin module 170.

Further referring to FIG. 4, as shown in the figure, the heat absorption portion 112, the heat absorption portion 122, the heat absorption portion 132, the heat absorption portion 142 and the heat absorption portion 152 have a flat bottom shape. In some embodiments, the heat absorption portion 112 of the first heat pipe 110 includes a base plate 412, two side walls 414 and a top wall 416. The two side walls 414 are connected between the base plate 412 and the top wall 416. Preferably, the base plate 412 has a flat bottom shape, and the two side walls 414 are extended upwardly from the base plate 412 and connected to the top wall 416.

Similarly, the heat absorption portion 122 of the second heat pipe 120 includes a base plate 422, two side walls 424 and a top wall 426. The two side walls 424 are connected between the base plate 422 and the top wall 426. Preferably, the base plate 422 has a flat bottom shape, and the two side walls 424 are extended upwardly from the base plate 422 and connected to the top wall 426.

The heat absorption portion 132 of the third heat pipe 130 includes a base plate 432, two side walls 434 and a top wall 436. The two side walls 434 are connected between the base plate 432 and the top wall 436. Preferably, the base plate 432 has a flat bottom shape, and the two side walls 434 are extended upwardly from the base plate 432 and connected to the top wall 436.

The heat absorption portion 142 of the forth heat pipe 140 includes a base plate 442, two side walls 444 and a top wall 446. The two side walls 444 are connected between the base plate 442 and the top wall 446. Preferably, the base plate 442 has a flat bottom shape, and the two side walls 444 are extended upwardly from the base plate 442 and connected to the top wall 446.

In addition, the heat absorption portion 152 of the fifth heat pipe 150 includes a base plate 452, two side walls 454 and a top wall 456. The two side walls 454 are connected between the base plate 452 and the top wall 456. Preferably, the base plate 452 has a flat bottom shape, and the two side walls 454 are extended upwardly from the base plate 452 and connected to the top wall 456.

It is worth noting that the base plate 412, the base plate 422, the base plate 432, the base plate 442 and the base plate 452 are preferably coplanar with each other and connected to the surface of the heat conduction block 192. In addition, the two side walls 414 of the first heat pipe 110 are respectively connected to one side wall 424 of the second heat pipe 120, another side wall 424 of the second heat pipe 120 is connected to one side wall 434 of the third heat pipe 130, another side wall 434 of the third heat pipe 130 is connected to one side wall 444 of the fourth heat pipe 140, another side wall 444 of the fourth heat pipe 140 is connected to one side wall 454 of the fifth heat pipe 150 to allow the heat pipe effectively contacting the surface of the heat conduction block 192 to uniformly remove the heat from the heat conduction block 192 with the heat pipe.

Further referring to FIG. 5, as shown in the figure, the heat pipe 500 may be utilized to form the first heat pipe 110, the second heat pipe 120, the third heat pipe 130, the fourth heat pipe 140 and/or the fifth heat pipe 150.

The heat pipe 500 includes a metal tube 510, an internal ring gear layer 520 and a powder sintered layer 530. The internal ring gear layer 520 are formed on an inner wall of the metal tube 510, and the powder sintered layer 530 is formed inside the internal ring gear layer 520. In addition, the internal ring gear layer 520 of the heat pipe 500 includes a groove depth 522 and a groove width 524.

It is worth noting that, the groove depth 522 of the internal ring gear layer 520 of the heat pipe 500 to form the first heat pipe 110 is about 40-60% of the groove depth of the other heat pipe, i.e. the groove depth of the second heat pipe 120, the third heat pipe 130, the fourth heat pipe 140 and/or fifth heat pipe 150. The groove width 524 of the internal ring gear layer 520 of the heat pipe 500 to form the first heat pipe 110 is about 30-50% of the groove width of the other heat pipe, i.e. the groove width of the second heat pipe 120, the third heat pipe 130, the fourth heat pipe 140 and/or fifth heat pipe 150.

In addition, in some embodiments, a diameter of metal powders of the powder sintered layer 530 of the heat pipe 500 to form the first heat pipe 110 is about 35-45% of the diameter of the metal powders of the powder sintered layer of the other heat pipe, i.e. the diameter of the metal powders of the powder sintered layer of the second heat pipe 120, the third heat pipe 130, the fourth heat pipe 140 and/or fifth heat pipe 150.

In some embodiments, the powder sintered layer 530 of the heat pipe 500 is made of metal powder, for example, copper metal powder or any other metal powder, or made of non-metal powder, without departing from the spirit and protection scope of the present invention.

Accordingly, the gravity heat dissipation device disclosed in the present invention may utilize the gravity heat pipe to effectively improve the performance of the vertically installed display card, reduce the operating temperature of the computing chip, and further improve the overall working efficiency of the electronics device. In addition, the gravity heat pipe is equipped with finer metal powder to form a sintered layer to effectively improve the capillary force so as to increase the heat dissipation performance. Furthermore, shallow grooves are used instead of deep grooves to further ensure the heat dissipation liquid smoothly moving therein to further improve the heat dissipation performance, thereby increasing the heat dissipation capacity of the gravity heat dissipation device. Therefore, the gravity heat dissipation device disclosed in the present invention is suitable for a vertically mounted graphics card device.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. A gravity heat dissipation device, comprising:
a fixing frame;
a heat conduction block installed in the fixing frame to contact a heat source;
a first heat pipe connected to the heat conduction block, wherein the first heat pipe comprises a heat absorption portion, a connection portion and a heat dissipation portion, wherein the connection portion of the first heat pipe is connected between the heat absorption portion of the first heat pipe and the heat dissipation portion of the first heat pipe, and the connection portion of the first heat pipe is located below the heat absorption portion of the first heat pipe and the heat dissipation portion of the first heat pipe; and
a second heat pipe connected to the heat conduction block and the first heat pipe, wherein the second heat pipe comprises a heat absorption portion, a first connection portion and a first heat dissipation portion, wherein the first connection portion of the second heat pipe is connected between the heat absorption portion of the second heat pipe and the first heat dissipation portion of the second heat pipe, and the first connection portion of the second heat pipe is located above the heat absorption portion of the second heat pipe and the first heat dissipation portion of the second heat pipe.

2. The gravity heat dissipation device according to claim 1, wherein the second heat pipe further comprises:
a second connection portion connected to and located below the heat absorption portion of the second heat pipe; and
a second heat dissipation portion connected to the second connection portion of the second heat pipe.

3. The gravity heat dissipation device according to claim 2, further comprising:
a third heat pipe connected to the heat conduction block and the second heat pipe, wherein the third heat pipe comprises a heat absorption portion, a first connection portion, a first heat dissipation portion, a second connection portion and a second heat dissipation portion, wherein the first connection portion of the third heat pipe is connected between the heat absorption portion of the third heat pipe and the first heat dissipation portion of the third heat pipe, and the first connection portion of the third heat pipe is located above the heat absorption portion of the third heat pipe and the first heat dissipation portion of the third heat pipe, the second connection portion of the third heat pipe is connected to and located below the heat absorption portion of the third heat pipe, and the second heat dissipation portion of the third heat pipe is connected to the second connection portion of the third heat pipe.

4. The gravity heat dissipation device according to claim 3, wherein the second heat pipe and the third heat pipe in sequence are respectively disposed symmetrically on both sides of the first heat pipe.

5. The gravity heat dissipation device according to claim 3, further comprising:
a fourth heat pipe connected to the heat conduction block and the third heat pipe, wherein the fourth heat pipe comprises a heat absorption portion, a connection portion and a heat dissipation portion, wherein the connection portion of the fourth heat pipe is connected between the heat absorption portion of the fourth heat pipe and the heat dissipation portion of the fourth heat pipe, and the connection portion of the fourth heat pipe is located below the heat absorption portion of the fourth heat pipe and located above the heat dissipation portion of the fourth heat pipe.

6. The gravity heat dissipation device according to claim 5, further comprising:
a fifth heat pipe connected to the heat conduction block and the fourth heat pipe, wherein the fifth heat pipe comprises a heat absorption portion, a connection portion and a heat dissipation portion, wherein the connection portion of the fifth heat pipe is connected to the heat absorption portion of the fifth heat pipe and the heat dissipation portion of the fifth heat pipe, and the connection portion of the fifth heat pipe is located below the heat absorption portion of the fifth heat pipe and above the heat dissipation portion of the fifth heat pipe.

7. The gravity heat dissipation device according to claim 6, wherein the second heat pipe, the third heat pipe, the fourth heat pipe and the fifth heat pipe in sequence are respectively disposed symmetrically on both sides of the first heat pipe.

8. The gravity heat dissipation device according to claim 6, further comprising:
a first heat dissipation fin module, wherein the heat absorption portion of the first heat pipe and the heat dissipation portion of the first heat pipe, the heat absorption portion of the second heat pipe and the first heat dissipation portion of the second heat pipe, the heat absorption portion of the third heat pipe and the first heat dissipation portion of the third heat pipe, the heat absorption portion of the fourth heat pipe, and the heat absorption portion of the fifth heat pipe are disposed inside the first heat dissipation fin module.

9. The gravity heat dissipation device according to claim 8, further comprising:
a second heat dissipation fin module is separately disposed with the first heat dissipation fin module up and down, wherein the second heat dissipation portion of the second heat pipe, the second heat dissipation portion of the third heat pipe, the heat dissipation portion of the fourth heat pipe and the heat dissipation portion of the fifth heat pipe are disposed inside the second heat dissipation fin module.

10. The gravity heat dissipation device according to claim 9, further comprising:
a module fixing bracket fixed on the first heat dissipation fin module and the second heat dissipation fin module; and
a fan module fixed on the module fixing bracket.

11. The gravity heat dissipation device according to claim 10, wherein the fan module comprises:
a fan fixing frame fixed on the module fixing bracket; and
a plurality of fans installed on the fan fixing frame.

12. The gravity heat dissipation device according to claim 1, wherein the first heat pipe comprises:
a metal tube;
an internal ring gear layer formed on an inner wall of the metal tube; and
a powder sintered layer formed inside the internal ring gear layer, wherein the internal ring gear layer of the first heat pipe comprises a groove depth and a groove width, wherein the groove depth of the internal ring gear layer of the first heat pipe is about 40-60% of a groove depth of the second heat pipe, the groove width of the internal ring gear layer of the first heat pipe is about 30-50% of a groove width of the second heat pipe, wherein a diameter of metal powders of the powder sintered layer of the first heat pipe is about 35-45% of a diameter of metal powders of a powder sintered layer of the second heat pipe.
